(19) United States
(12) Patent Application Publication
(10) Pub. No.: US 2008/0197356 A1
(43) Pub. Date: Aug. 21, 2008

(54) THIN FILM TRANSISTOR SUBSTRATE AND METHOD OF MANUFACTURING THE SAME

(75) Inventors: Deok-Hoi KIM, Seongnam-si (KR); Chung Yi, Yongin-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 12/021,079

(22) Filed: Jan. 28, 2008

(30) Foreign Application Priority Data
Feb. 21, 2007 (KR) 10-2007-0017555

(51) Int. Cl. H01L 27/12; H01L 21/84; H01L 21/336

(52) U.S. Cl. 257/71; 438/155; 438/158; 257/E27.112; 257/E21.414; 257/E21.7

(57) ABSTRACT

A thin film transistor (TFT) substrate and a method of manufacturing the same in which the surface of a data pattern is implanted with ions to increase the adhesion force with a passivation layer formed by a subsequent process. The TFT substrate includes: an active layer having a channel region formed of a semiconductor and source and drain regions doped with impurities; a data pattern formed on the active layer and including source and drain electrodes, the surface of which is implanted with ions to increase hydrophobicity and roughness; a passivation layer formed on the data pattern and including a pixel contact hole exposing a portion of the drain electrode; and a pixel electrode formed on the passivation layer and connected to the drain electrode through the pixel contact hole, and a method of manufacturing the same.

### CROSS-REFERENCE TO RELATED APPLICATION

This application claims priority to and the benefit of Korean Patent Application No. 10-2007-0017555, filed on Feb. 21, 2007, the disclosure of which is incorporated herein by reference in its entirety.

### BACKGROUND OF THE INVENTION

1. Field of the Invention

The present invention relates to a thin film transistor (TFT) substrate and, more particularly, to a TFT substrate and a method of manufacturing the same which can increase the adhesion force between a data pattern and a passivation layer.

2. Description of the Related Art

A liquid crystal display (LCD) device displays an image by controlling the light transmittance of liquid crystal cells arranged in a matrix form on a liquid crystal panel in response to a video signal. The LCD device includes a thin film transistor (TFT) substrate, a color filter substrate facing the TFT substrate, and liquid crystals disposed between the TFT substrate and the color filter substrate.

The color filter substrate includes a black matrix for preventing light leakage and a color filter for displaying color, a common electrode for generating a vertical electric field with a pixel electrode, and an upper alignment layer coated thereon for liquid crystal alignment.

The TFT substrate includes gate and data lines crossing each other, TFTs formed at respective intersections of the gate and data lines, pixel electrodes connected to the TFTs, and an alignment layer coated for liquid crystal alignment.

During the formation of the TFT, source and drain metal layers are formed and then an organic passivation layer is formed on the top thereof. Unfortunately, the metal layers may be corroded by the etchant used to define the transparent electrode thereby reducing the adhesion force between the source and drain metal layers and the organic passivation layer. In an attempt to solve this problem, silicon nitride (SiNx) as a passivation layer is deposited to a predetermined thickness between the source and drain metal layers and the organic passivation layer to increase the adhesion force. However, the adhesion defect problem is not completely solved.

### SUMMARY OF THE INVENTION

The present invention, according to one aspect, provides a thin film transistor (TFT) substrate and a method of manufacturing the same in which the surface of a data pattern, such as that for the source and drain electrodes, is implanted with ions to increase the adhesion force with a passivation layer formed by a subsequent process.

In one exemplary embodiment, a thin film transistor (TFT) substrate includes: an active layer including a channel region formed of a semiconductor and source and drain regions doped with impurities; a data pattern formed on the active layer and including source and drain electrodes implanted with ions to increase hydrophobicity and roughness; a passivation layer formed on the data pattern and including a pixel contact hole exposing a portion of the drain electrode; and a pixel electrode formed on the passivation layer and connected to the drain electrode through the pixel contact hole.

The TFT substrate may further include: a gate insulating layer formed on the active layer; a gate pattern formed on the gate insulating layer and including a gate electrode; and an interlayer insulating layer formed on the gate pattern and including first and second contact holes exposing a portion of the source and drain regions.

The TFT substrate may further include: a gate pattern including a gate electrode; a gate insulating layer formed between the gate pattern and the active layer; and an ohmic contact layer formed of impurity-doped polysilicon on the active layer and exposing the channel region.

The passivation layer may be an organic passivation layer.

The data pattern may be formed of one selected from the group consisting of molybdenum tungsten (MoW), molybdenum (Mo), titanium (Ti), and titanium nitride (TiN).

The surface of the data pattern may be implanted with carbon ions to increase hydrophobicity and roughness.

The surface of the interlayer insulating layer may be implanted with ions.

The overall surface of the data pattern and the interlayer insulating layer may be implanted with carbon ions.

In another exemplary embodiment, a thin film transistor (TFT) substrate includes: an active layer formed on a substrate and including a channel region formed of a semiconductor and impurity-doped source and drain regions formed on both sides of the channel region; a gate insulating layer covering the active layer; a gate pattern formed on the gate insulating layer and including a gate line and a gate electrode connected to the gate line; an interlayer insulating layer formed on the gate pattern and including a first contact hole exposing a portion of the source region and a second contact hole exposing a portion of the drain region; a data pattern, of which surface is implanted with ions, formed on the interlayer insulating layer, and including a source electrode connected to the source region through the first contact hole and a drain electrode connected to the drain region through the second contact hole; a passivation layer formed on the data pattern and including a pixel contact hole exposing a portion of the drain electrode; and a pixel electrode formed on the passivation layer and connected to the drain electrode through the pixel contact hole.

The gate pattern may include: a storage line formed parallel to the gate line; and a storage electrode connected to the storage line and overlapping a portion of the drain electrode or the pixel electrode.

In another exemplary embodiment, a thin film transistor (TFT) substrate includes: a gate pattern formed on a substrate and including a gate line and a gate electrode connected to the gate line; a gate insulating layer covering the gate pattern; an active layer formed on the gate insulating layer and including a channel region formed of a semiconductor and impurity-doped source and drain regions formed on both sides of the channel region; an ohmic contact layer formed of impurity-doped polysilicon on the active layer and exposing the channel region; a data pattern of which surface is implanted with ions and including source and drain electrodes respectively formed on the ohmic contact layer; a passivation layer formed on the data pattern and including a pixel contact hole exposing a portion of the drain electrode; and a pixel electrode formed on the passivation layer and connected to the drain electrode through the pixel contact hole.

In another exemplary embodiment, a method of manufacturing a thin film transistor substrate includes: forming an active layer including a channel region formed of a semiconductor and impurity-doped source and drain regions; forming a data pattern on the active layer, the data pattern including source and drain electrodes; implanting ions into the surface of the data pattern to increase hydrophobicity and roughness; forming a passivation layer on the data pattern, the passivation layer including a pixel contact hole exposing a portion of the drain electrode; and forming a pixel electrode on the passivation layer, the pixel electrode being connected to the drain electrode through the pixel contact hole.

The method may further include: forming a gate insulating layer on the active layer; forming a gate pattern including a gate electrode on the gate insulating layer; and forming an interlayer insulating layer on the gate pattern, the interlayer insulating layer including first and second contact holes exposing a portion of the source and drain regions.

The method may further include: forming a gate pattern including a gate electrode; forming a gate insulating layer between the gate pattern and the active layer; and forming an ohmic contact layer on the active layer.

The passivation layer may be formed of an organic passivation layer.

The data pattern may be formed of one selected from the group consisting of molybdenum tungsten (MoW), molybdenum (Mo), titanium (Ti), and titanium nitride (TiN).

The process of implanting ions may include implanting carbon ions into the surface of the data pattern

The process of implanting ions may be selectively performed only to a region where the data pattern is formed.

The process of implanting ions may be performed to the overall surface of the data pattern and the interlayer insulating layer.

In another exemplary embodiment, a method of manufacturing a thin film transistor, includes: forming an active layer on a substrate, the active layer including a channel region formed of a semiconductor and impurity-doped source and drain regions formed on both sides of the channel region; forming a gate insulating layer to cover the active layer; forming a gate pattern on the gate insulating layer, the gate pattern including a gate line and a gate electrode connected to the gate line; forming an interlayer insulating layer on the gate pattern, the interlayer insulating layer including a first contact hole exposing a portion of the source region and a second contact hole exposing a portion of the drain region; forming a data pattern on the interlayer insulating layer, the data pattern including a source electrode connected to the source region through the first contact hole and a drain electrode connected to the drain region through the second contact hole; implanting ions into the surface of the data pattern; forming a passivation layer on the data pattern, the passivation layer including a pixel contact hole exposing a portion of the drain electrode; and forming a pixel electrode on the passivation layer, the pixel electrode being connected to the drain electrode through the pixel contact hole.

The process of forming the gate pattern may include forming a storage line parallel to the gate line, and a storage electrode connected to the storage line and overlapping a portion of the drain electrode or the pixel electrode.

In another exemplary embodiment, a method of manufacturing a thin film transistor includes: forming a gate pattern on a substrate, the gate pattern including a gate line and a gate electrode connected to the gate line; forming a gate insulating layer to cover the gate pattern; forming an active layer on the gate insulating layer, the active layer including a channel region formed of a semiconductor and impurity-doped source and drain regions formed on both sides of the channel region; forming an ohmic contact layer on the active layer; forming a data pattern on the ohmic contact layer, the data pattern including source and drain electrodes respectively connected to the source and drain regions; implanting ions into the surface of the data pattern; forming a passivation layer on the data pattern, the passivation layer including a pixel contact hole exposing a portion of the drain electrode; and forming a pixel electrode on the passivation layer, the pixel electrode being connected to the drain electrode through the pixel contact hole.

### BRIEF DESCRIPTION OF THE DRAWINGS

The above and other features of the present invention will be described in reference to certain exemplary embodiments thereof with reference to the attached drawings, in which:

FIG. 1 is a plan view of a thin film transistor (TFT) substrate in accordance with a first exemplary embodiment of the present invention;

FIG. 2 is a cross-sectional view taken along line I-I′ of FIG. 1;

FIGS. 3A to 3G are cross-sectional views illustrating a method of manufacturing the TFT substrate in accordance with the first exemplary embodiment of the present invention;7

FIG. 4 is a cross-sectional view illustrating an example of an ion implanting process in accordance with the present invention;

FIG. 5 is a cross-sectional view illustrating another example of the ion implanting process in accordance with the present invention;

FIG. 6 is a cross-sectional view illustrating the result of the ion implanting process in accordance with the example of FIG. 5;

FIG. 7 is a plan view of a TFT substrate in accordance with a second exemplary embodiment of the present invention;

FIG. 8 is a cross-sectional view taken along line II-II′ of FIG. 7; and

FIGS. 9A to 9F are cross-sectional views illustrating a method of manufacturing the TFT substrate in accordance with the second exemplary embodiment of the present invention.

### DETAILED DESCRIPTION OF THE INVENTION

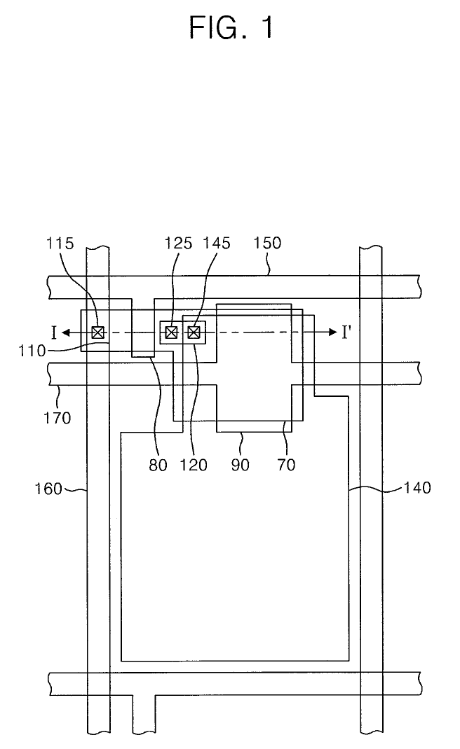

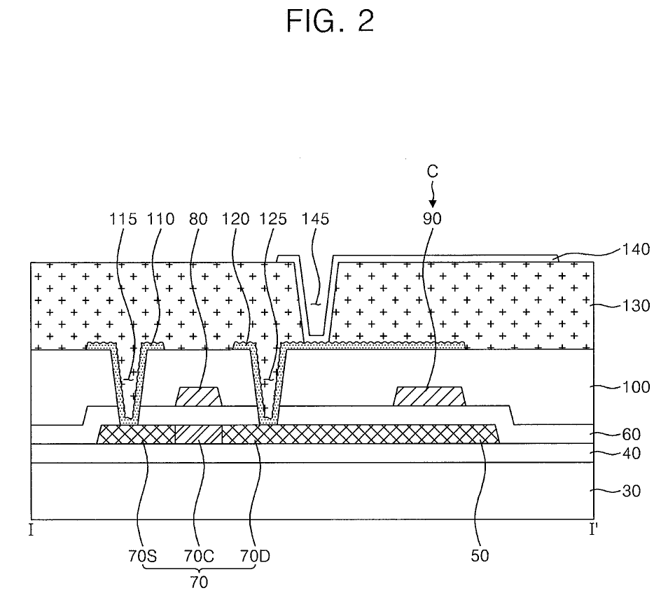

FIG. 1 is a plan view of a thin film transistor (TFT) substrate in accordance with a first exemplary embodiment of the present invention, and FIG. 2 is a cross-sectional view taken along line I-I′ of FIG. 1.

Referring to FIGS. 1 and 2, the TFT substrate in accordance with the first exemplary embodiment of the present invention includes an active layer 70, a gate insulating layer 60, a gate pattern, an interlayer insulating layer 100, a data pattern, a passivation layer 130, and a pixel electrode 140.

The active layer 70 is formed on a lower substrate 30 with a buffer layer 40 disposed therebetween and includes a channel region 70C formed of a semiconductor, and impurity-doped source and drain regions 70S and 70D formed on both sides of the channel region 70C.

The gate insulating layer 60 is formed on the active layer 70 to cover the active layer 70.

The gate pattern is formed on the gate insulating layer 60 and includes a gate line 150 and a gate electrode 80 connected to the gate line 150. Moreover, the gate pattern includes a storage line 170 formed parallel to the gate line 150 and a storage electrode 90 connected to the storage line 170 and overlapping a portion of a drain electrode 120 or the pixel electrode 140.

The interlayer insulating layer 100 is formed on the gate pattern and includes a first contact hole 115 exposing a portion of the source region 70S and a second contact hole 125 exposing a portion of the drain region 70D.

The data pattern is formed on the interlayer insulating layer 100 and includes a source electrode 110 connected to the source region 70S through the first contact hole 115 and a drain electrode 120 connected to the drain region 70D through the second contact hole 125. The surface of the data pattern is implanted with ions and, in the present embodiment, implanted with carbon ions (C⁺). As a result, hydrophobicity and roughness are increased in the surface of the data pattern. Only the surface of the data pattern may be selectively implanted, or the overall surface of the data pattern and the interlayer insulating layer 100 may be implanted. The data pattern may be formed of molybdenum tungsten (MoW), molybdenum (Mo), titanium (Ti), or titanium nitride (TiN).

In the present embodiment, although an ion implanting process using carbon ions (C⁺) is described, it is possible to use any method capable of increasing the roughness of the surface of the data pattern, such as a plasma process using ions having a high molecular weight, and the like.

The passivation layer 130 is formed on the data pattern and includes a pixel contact hole 145 exposing a portion of the drain electrode 120. The passivation layer 130 may be formed as an organic passivation layer 130.

The pixel electrode 140 is formed on the passivation layer 130 and connected to the drain electrode 120 through the pixel contact hole 145.

The TFT substrate includes the gate line 150 and a data line 160 crossing each other with the interlayer insulating layer 100 disposed therebetween on the lower substrate 30, a TFT formed at each intersection thereof, the pixel electrode 140 formed in each pixel area, and a storage capacitor C for preventing a change of a pixel voltage signal charged in the pixel electrode 140.

The gate line 150 supplies a gate signal to the gate electrode 80 of the TFT.

The data line 160 supplies a pixel voltage to the source electrode 110 of the TFT. The data line 160 crosses the gate line 150 with the interlayer insulating layer 100 disposed therebetween.

The interlayer insulating layer 100 insulates the gate pattern including the gate line 150 and the gate electrode 80 from the data pattern including the data line 160, the source electrode 110 and the drain electrode 120.

The TFT allows the pixel voltage signal of the data line 160 to be charged in the pixel electrode 140 and maintained constant in response to the gate signal of the gate line 150. The TFT may be formed of a metal oxide semiconductor (MOS) transistor, such as an N-type MOS transistor or a P-type MOS transistor, or a complementary MOS (CMOS) transistor; however, the following description will be of a TFT formed of an N-type MOS transistor.

The TFT includes the gate electrode 80 connected to the gate line 150, the source electrode 110 included in the data line 160, the drain electrode 120 connected to the pixel electrode 140 through the pixel contact hole 145 penetrating the passivation layer 130, and the active layer 70 forming a channel between the source electrode 110 and the drain electrode 120 by the gate electrode 80.

The active layer 70 is formed on the lower substrate 30 with the buffer layer 40 disposed therebetween. The gate electrode 80 connected to the gate line 150 overlaps the channel region 70C of the active layer 70 with the gate insulating layer 60 disposed therebetween. The source electrode 110 and the drain electrode 120 are insulated from the gate electrode 80 with the interlayer insulating layer 100 disposed therebetween. The source electrode 110, connected to the data line 160, and the drain electrode 120 are respectively connected to the source region 70S and the drain region 70D of the active layer 70, into which n+ impurities are injected, through the first contact hole 115 and the second contact hole 125 penetrating the interlayer insulating layer 100 and the gate insulating layer 60.

The active layer 70 may further include a lightly doped drain (LDD) region (not shown) into which n− impurities are injected, formed between the channel region 70C and the source and drain regions 70S and 70D to reduce the off-current.

The pixel electrode 140 is formed of a transparent conductive layer in the pixel area and connected to the drain electrode 120 of the TFT. Accordingly, a vertical electric field is generated between the pixel electrode 140 supplied with the pixel signal through the TFT and a common electrode supplied with a reference voltage. Liquid crystal molecules having dielectric anisotropy disposed between the color filter substrate and the TFT substrate are rotated by the generated vertical electric field. The light transmittance transmitting the pixel region differs in accordance with the amount of rotation of the liquid crystal molecules and thereby a gray scale is represented.

The storage capacitor C allows the pixel voltage signal charged in the pixel electrode 140 to be stably maintained until the next pixel voltage signal is charged. The storage capacitor C is formed to overlap the storage electrode 90 connected to the storage line 170 with the interlayer insulating layer 100 and the passivation layer 130 disposed therebetween and maintains the voltage charged in the pixel electrode 140 constant.

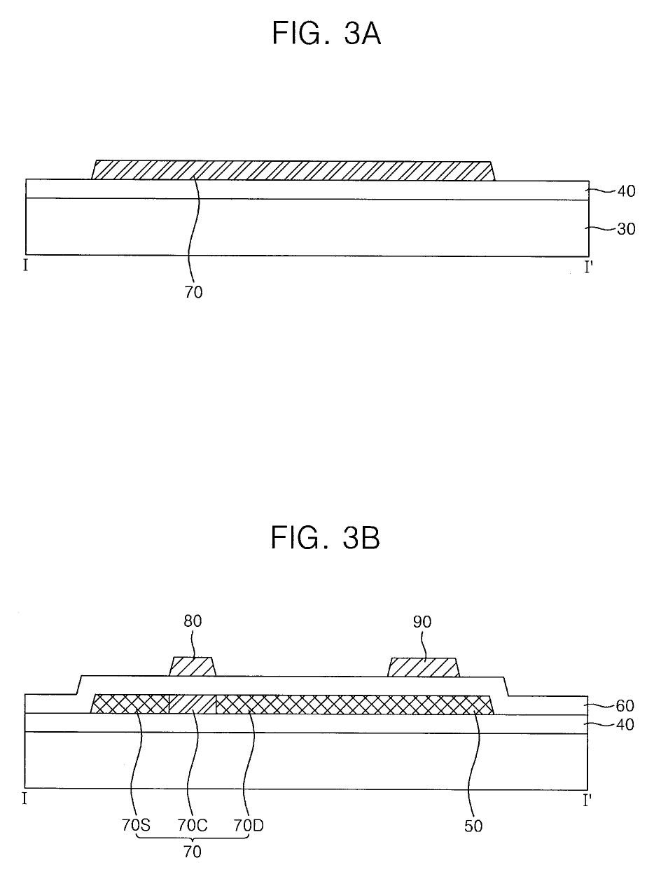

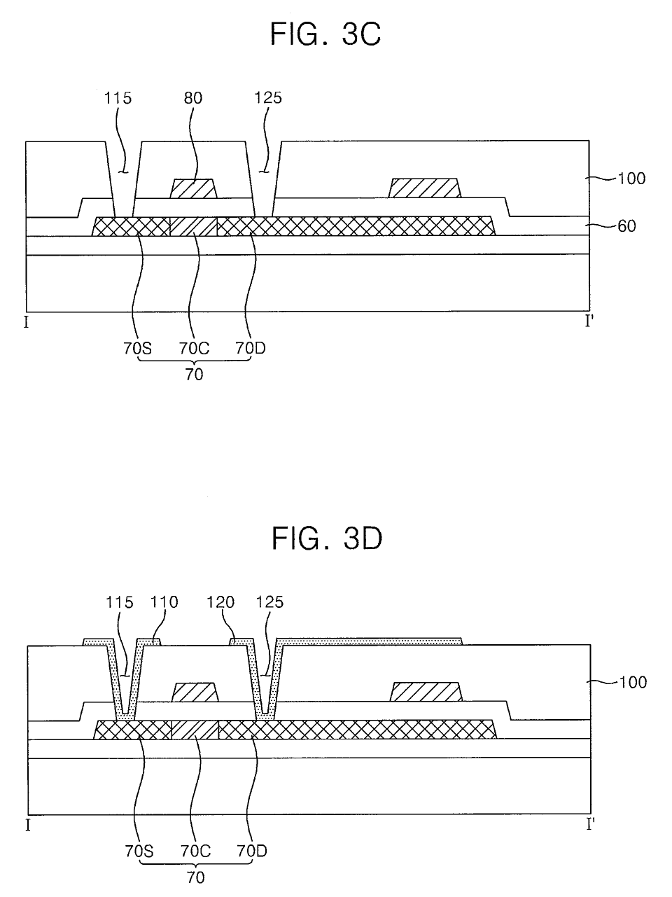

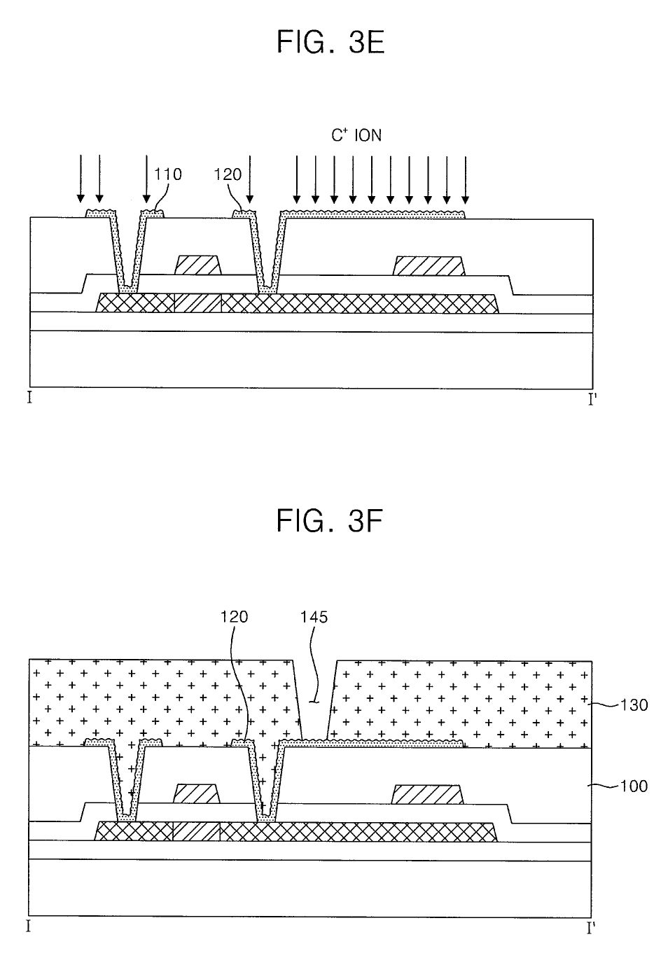

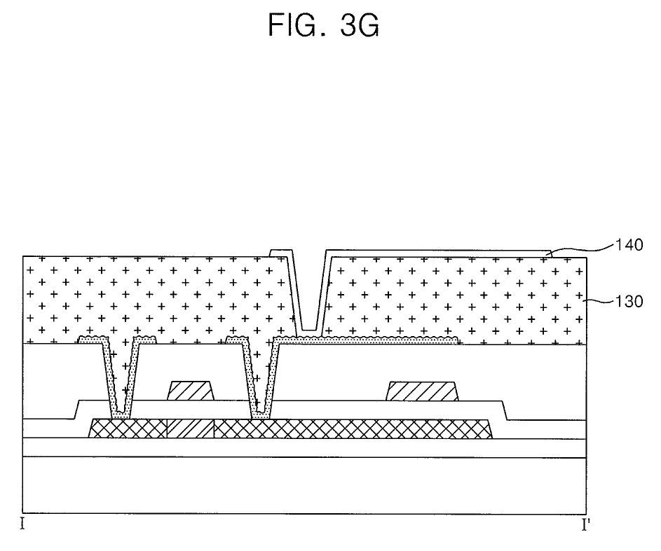

FIGS. 3A to 3G are cross-sectional views illustrating a method of manufacturing the TFT substrate in accordance with the first exemplary embodiment of the present invention.

Referring to FIG. 3A, a buffer layer 40 is formed on a lower substrate 30, and an active layer 70 is formed thereon. The buffer layer 40 is formed by depositing an inorganic insulating material such as silicon oxide (SiO₂) on the overall surface of the lower substrate 30.

The active layer 70 is formed in such a manner that amorphous silicon is deposited on the buffer layer 40 and crystallized by laser irradiation to form polysilicon 50 shown in FIG. 3B, and then the polysilicon 50 is patterned by photolithography and etching processes.

As shown in FIG. 3B, a gate insulating layer 60 is formed on the buffer layer 40 on which the active layer 70 is formed, and a gate pattern including a gate electrode 80, a gate line, a storage electrode 90, and a storage line is formed thereon.

The gate insulating layer 60 is formed by depositing an inorganic insulating material such as silicon oxide (SiO₂) on the overall surface of the buffer layer 40 on which the active layer 70 is formed.

The gate pattern is formed in such a manner that a gate metal layer is formed of Al, Ti, MoW, copper (Cu), and an alloy thereof, or in a multi-layered structure including the same, on the substrate 30 on which the gate insulating layer 60 is formed, and then the gate metal layer is patterned by photolithography and etching processes.

Subsequently, n-type impurities are injected into the active layer 70 using a mask to form a source region 70S and a drain region 70D of the active layer 70 not overlapping the gate electrode 80. Such source and drain regions 70S and 70D of the active layer 70 face each other with a channel region 70C overlapping the gate electrode 80, disposed therebetween. An LDD region into which a small amount of impurities is injected, compared to the source and drain regions 70S and 70D, may be formed between the source region 70S and the channel region 70C and between the drain region 70D and the channel region 70C.

Referring to FIG. 3C, an interlayer insulating layer 100 is formed on the gate insulating layer 60 on which the gate pattern is formed, and then a first contact hole 115 exposing a portion of the source region 70S of the active layer 70 and a second contact hole 125 exposing a portion of the drain region 70D of the active layer 70 are formed on the interlayer insulating layer 100.

The interlayer insulating layer 100 is formed by depositing an inorganic insulating material such as silicon oxide (SiO₂) on the overall surface of the gate insulating layer 60 on which the gate pattern including the gate line 150 and the gate electrode 80 is formed.

Subsequently, the first and second contact holes 115 and 125 penetrating the interlayer insulating layer 100 and the gate insulating layer 60 to expose the source and drain regions 70S and 70D of the active layer 70 are formed by photolithography and etching processes.

Referring to FIG. 3D, a data pattern including a data line 160, a source electrode 110, and a drain electrode 120 is formed on the interlayer insulating layer 100.

The data pattern including the data line 160, the source electrode 110, and the drain electrode 120 is formed by forming source and drain metal layers on the interlayer insulating layer 100 and then patterning the source and drain metal layers by photolithography and etching processes.

The data pattern may be formed of MoW, Mo, Ti, or TiN.

The source electrode 110 is connected to the source region 70S of the active layer 70 through the first contact hole 115, and the drain electrode 120 is connected to the drain region 70D of the active layer 70 through the second contact hole 125.

Referring to FIG. 3E, the surface of the data pattern including the data line, the source electrode 110, and the drain electrode 120 is implanted with carbon ions (C⁺).

In particular, the surfaces of the data line, the drain electrode 120 and the source electrode 110 are implanted with carbon ions (C⁺) using CH₄ or CF₄ as an ion source gas.

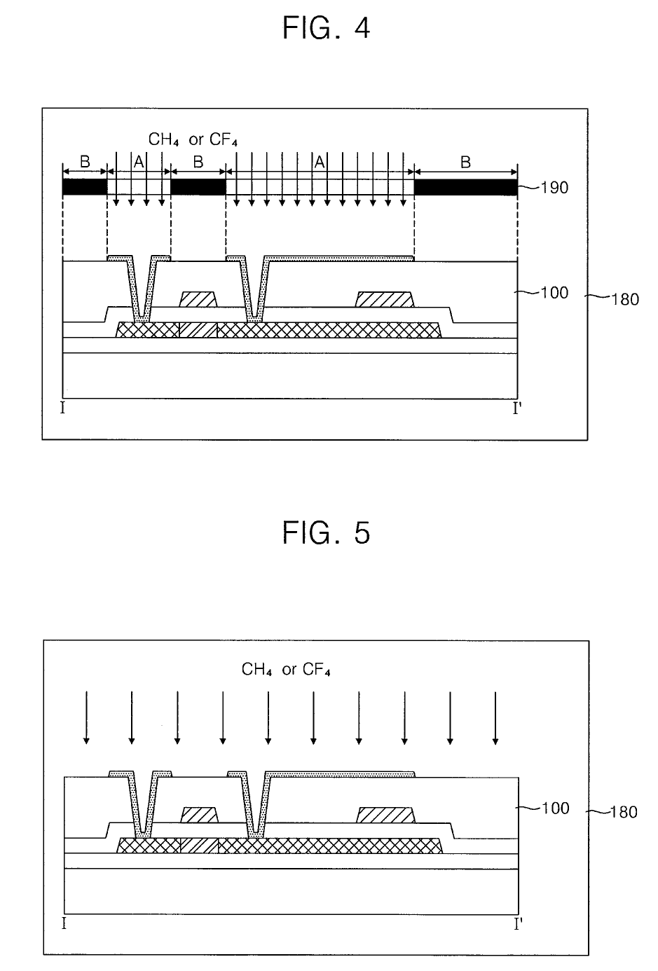

FIG. 4 is a cross-sectional view illustrating an example of an ion implanting process in accordance with the present invention.

Referring to FIG. 4, the ion implanting process in accordance with an example of the present invention loads a substrate including the data pattern formed on the interlayer insulating layer 100 into a chamber 180. Then, a source gas, such as CH₄ or CF₄, and argon (Ar) is injected into the chamber 180. A mask 190 composed of transmitting regions A and non-transmission regions B is provided inside the chamber 180. Carbon ions (C⁺) produced by the argon (Ar) transmit the transmission regions A other than the non-transmission regions B and thereby only the surface of the data pattern is selectively implanted with carbon ions (C⁺). The roughness of the surface of the data pattern implanted like this is increased and, as a result, the adhesion force with an organic layer formed by a subsequent process is increased, thus preventing the data pattern from being separated from the organic layer. Moreover, the hydrophobicity is increased to reduce the effect of the etchant. Argon (Ar), nitrogen (N₂), phosphorus (P), and boron (B) may be used as the ions capable of increasing the surface roughness besides the carbon ions (C⁺).

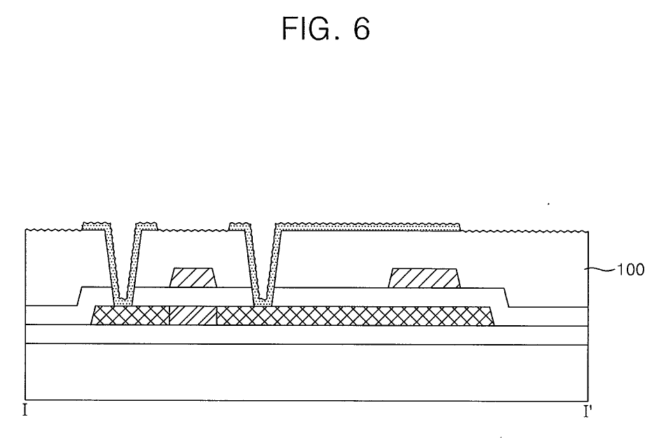

FIG. 5 is a cross-sectional view illustrating another example of the ion implanting process in accordance with the present invention, and FIG. 6 is a cross-sectional view illustrating the result of the ion implanting process in accordance with the example of FIG. 5.

Referring to FIG. 5, the ion implanting process in accordance with another example of the present invention loads a substrate including the data pattern formed on the interlayer insulating layer 100 into a chamber 180. Then, a source gas, such as CH₄ or CF₄, and argon (Ar) is injected into the chamber 180. The overall surface of the data pattern and the interlayer insulating layer 100 are implanted with carbon ions (C⁺) produced by the argon (Ar). The roughness of the surface of the data pattern and the interlayer insulating layer 100 implanted with carbon ions (C⁺) is increased and, as a result, the adhesion force with an organic layer formed by a subsequent process is increased, thus preventing the data pattern from being separated from the organic layer. Moreover, the hydrophobicity is increased to reduce the effect of the etchant.

As shown in FIG. 6, the overall surface of the data pattern and the interlayer insulating layer 100 implanted with carbon ions (C⁺) in accordance with another example of the present invention shows increased hydrophobicity and roughness. Accordingly, it is possible to increase the adhesion force with the passivation layer remarkably.

Referring back to FIG. 3F, a passivation layer 130 is formed on the interlayer insulating layer 100 on which the data pattern is formed, and a pixel contact hole 145 exposing a portion of the drain electrode 120 is formed on the passivation layer 130.

The passivation layer 130 is formed by depositing an organic insulating material such as photo acryl on the overall surface of the interlayer insulating layer 100 on which the data pattern is formed. Since the organic passivation layer 130 has a poor adhesion force with a metal layer formed as the data pattern, the passivation layer 130 may be separated from the metal layer. Accordingly, the surface of the data pattern or the overall surface of the data pattern and the interlayer insulating layer 100 is implanted with carbon ions (C⁺) to increase the roughness, thus increasing the adhesion force.

Subsequently, the passivation layer 130 is penetrated by photolithography and etching processes to expose the drain electrode 120 of the TFT.

Referring to FIG. 3G, a pixel electrode pattern including a pixel electrode 140 is formed on the passivation layer 130.

The pixel electrode pattern including the pixel electrode 140 is formed by depositing a transparent conductive layer such as indium tin oxide (ITO), indium zinc oxide (IZO), and indium tin zinc oxide (ITZO) on the passivation layer 130 and then patterning the transparent conductive layer by photolithography and etching processes.

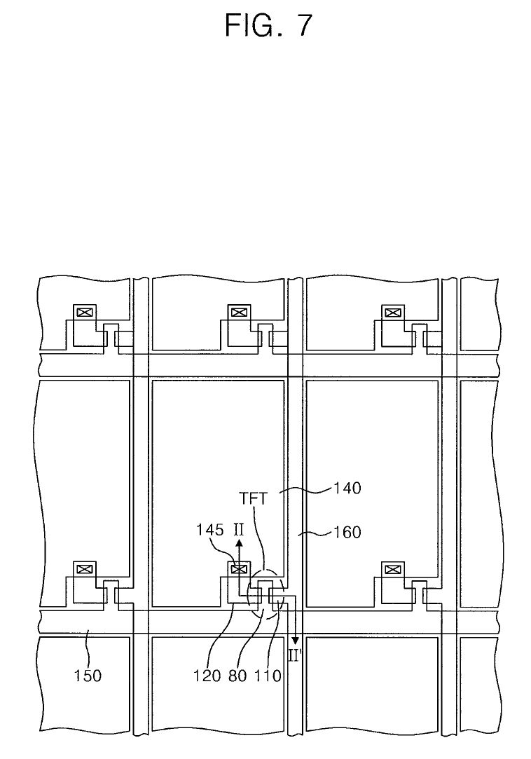

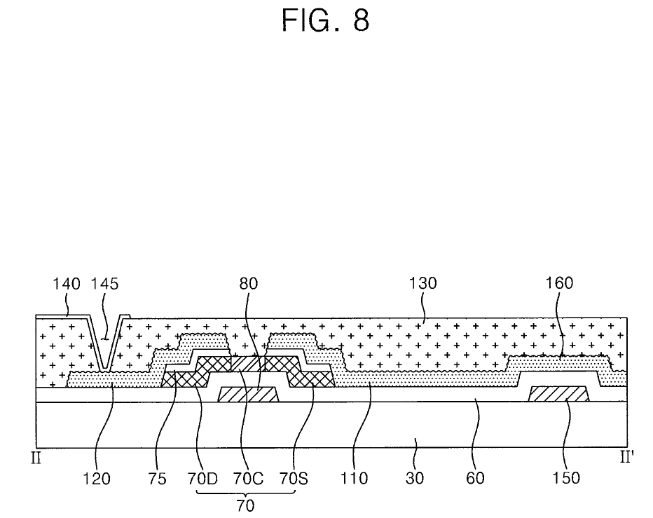

FIG. 7 is a plan view of a TFT substrate in accordance with a second exemplary embodiment of the present invention, and FIG. 8 is a cross-sectional view taken along line II-II′ of FIG. 7.

Referring to FIGS. 7 and 8, the TFT substrate includes a gate pattern, a gate insulating layer 60, an active layer 70, a data pattern, a passivation layer 130, and a pixel electrode 140.

The gate pattern is formed on a lower substrate 30 with a buffer layer 40 disposed therebetween and includes a gate line 150 and a gate electrode 80 connected to the gate line 150.

The gate insulating layer 60 is formed on the gate pattern to cover the gate pattern.

The active layer 70 is formed on the gate insulating layer 60 to form a channel of a TFT, and an ohmic contact layer 75 is formed on the active layer 70 to reduce the contact resistance between a source electrode 110 and a drain electrode 120.

The active layer 70 includes a channel region 70C formed of a semiconductor on the gate insulating layer 60, and impurity-doped source and drain regions 70S and 70D formed on both sides of the channel region 70C.

The active layer 70 is formed in such a manner that amorphous silicon is deposited on the gate insulating layer 60 and crystallized by solid phase crystallization (SPC) to form polysilicon, and then the polysilicon is patterned by photolithography and etching processes. The ohmic contact layer 75 is formed in such a manner that amorphous silicon doped with an n-type impurity or a p-type impurity is deposited and crystallized to form polysilicon at the same time during the amorphous silicon crystallization, and then the polysilicon is patterned by photolithography and etching processes. Accordingly, the electron mobility of the active layer 70 and the ohmic contact layer 75 is increased to further improve the TFT characteristics.

The data pattern is formed on the gate insulating layer 60 and the active layer 70 and includes the source electrode 110 and the drain electrode 120. The surface of the data pattern is implanted with carbon ions (C⁺) to increase the hydrophobicity and roughness. Here, only the surface of the data pattern may be selectively implanted, or the overall surface of the data pattern and the gate insulating layer 60 may be implanted.

The passivation layer 130 is formed on the data pattern and includes a pixel contact hole 145 exposing a portion of the drain electrode 120. The passivation layer 130 may be formed of an organic passivation layer 130.

The pixel electrode 140 is formed on the passivation layer 130 and connected to the drain electrode 120 through the pixel contact hole 145.

Since the functions of the other elements are the same as the first exemplary embodiment, their detailed description will be omitted.

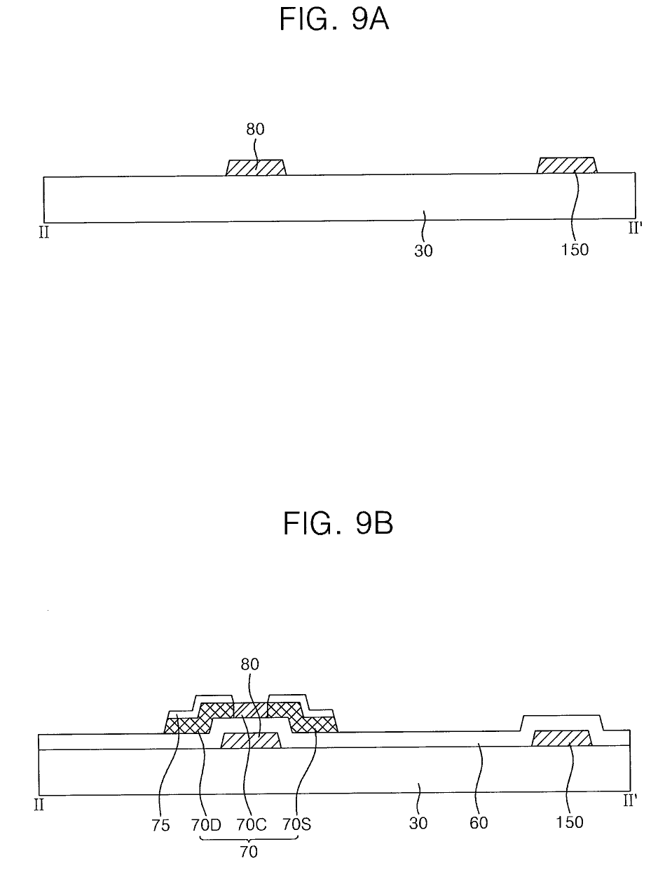

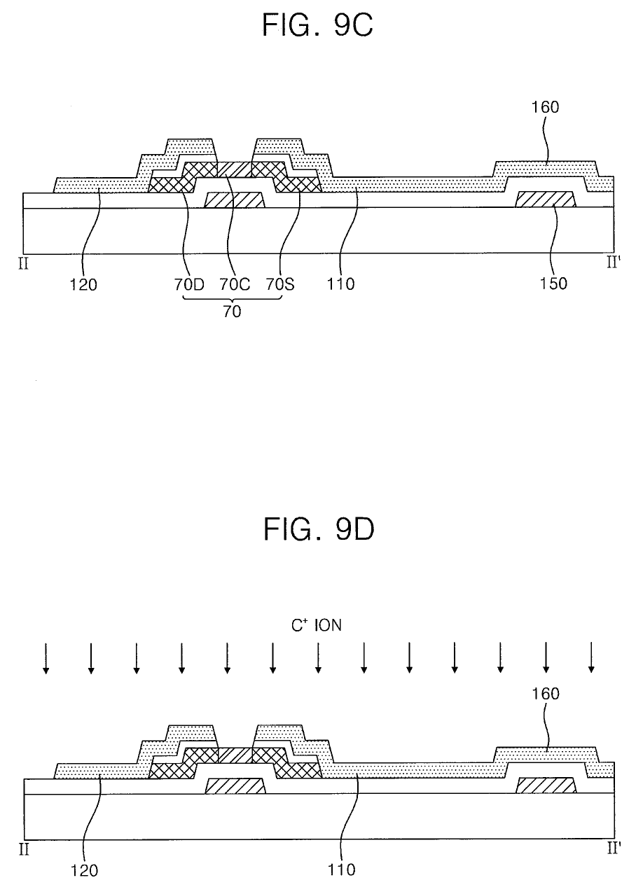

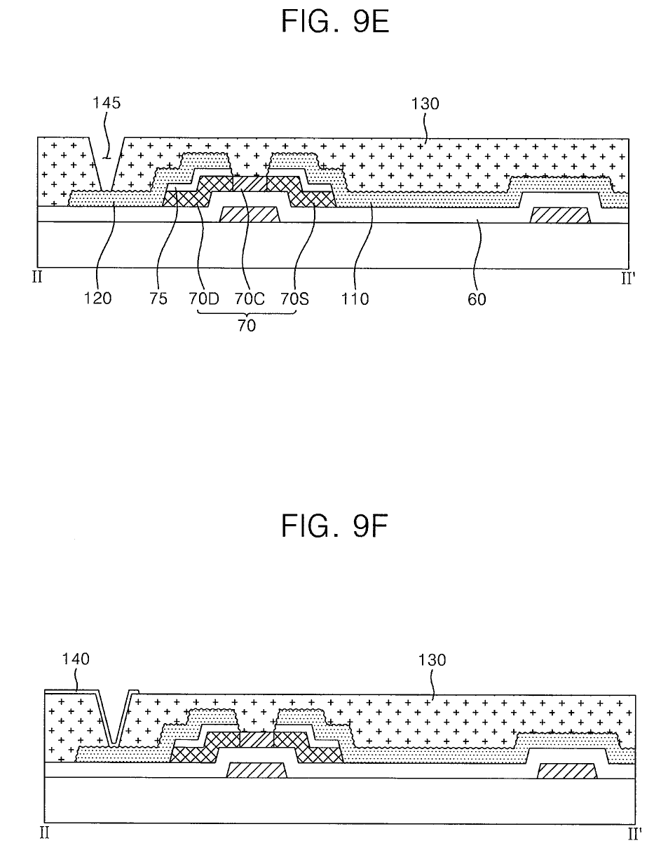

FIGS. 9A to 9F are cross-sectional views illustrating a method of manufacturing the TFT substrate in accordance with the second exemplary embodiment of the present invention.

Referring to FIG. 9A, a gate pattern including a gate electrode 80 and a gate line 150 is formed on a lower substrate 30.

The gate pattern is formed in such a manner that a gate metal layer is formed of Al, Ti, MoW, Cu, and an alloy thereof, or in a multi-layered structure including the same, on the substrate 30, and then the gate metal layer is patterned by photolithography and etching processes.

Referring to FIG. 9B, a gate insulating layer 60, an active layer 70, and an ohmic contact layer 75 are formed of an inorganic insulating material such as silicon oxide (SiO₂) on the substrate 30 on which the gate pattern is formed.

The active layer 70 and the ohmic contact layer 75 are formed in such a manner that amorphous silicon is deposited on the gate insulating layer 60 and crystallized by laser irradiation to form polysilicon, and then the polysilicon is patterned by photolithography and etching processes.

Subsequently, n-type or p-type impurities are injected into the active layer 70 and the ohmic contact layer 75 using a mask to form a source region 70S and a drain region 70D of the active layer 70 not overlapping the gate electrode 80. Such source and drain regions 70S and 70D of the active layer 70 face each other with a channel region 70C overlapping the gate electrode 80 disposed therebetween. An LDD region into which a small amount of impurities is injected, compared to the source and drain regions 70S and 70D, may be formed between the source region 70S and the channel region 70C and between the drain region 70D and the channel region 70C.

Referring to FIG. 9C, a data pattern including a data line 160, a source electrode 110, and a drain electrode 120 is formed on the active layer 70.

The data pattern including the data line 160, the source electrode 110, and the drain electrode 120 is formed by forming source and drain metal layers on the active layer 70 and then patterning the source and drain metal layers by photolithography and etching processes.

The data pattern may be formed of MoW, Mo, Ti, or TiN. Referring to FIG. 9D, the surface of the data pattern including the data line 160, the source electrode 110, and the drain electrode 120 is implanted with carbon ions (C⁺).

In the following, since the ion implanting process is the same as the first exemplary embodiment shown in FIGS. 4 to 6, a detailed description thereof will be omitted.

Referring to FIG. 9E, a passivation layer 130 is formed on the gate insulating layer 60, on which the data pattern is formed, and on the source and drain metal layers. A pixel contact hole 145 exposing a portion of the drain electrode 120 is formed on the passivation layer 130.

The passivation layer 130 is formed by depositing an organic insulating material such as photo acryl on the overall surface of the gate insulating layer 60, on which the data pattern is formed, and the source and drain metal layers. Since the organic passivation layer 130 has a poor adhesion force with a metal layer formed as the data pattern, the passivation layer 130 may be separated from the metal layer. Accordingly, the surface of the data pattern or the overall surface of the data pattern and the gate insulating layer 60 is implanted with carbon ions (C⁺) to increase the roughness, thus increasing the adhesion force. Moreover, the hydrophobicity is increased to reduce the effect of the etchant.

Subsequently, the passivation layer 130 is penetrated by photolithography and etching processes to expose the drain electrode 120 of the TFT.

Referring to FIG. 9F, a pixel electrode pattern including a pixel electrode 140 is formed on the passivation layer 130.

The pixel electrode pattern including the pixel electrode 140 is formed by depositing a transparent conductive layer such as ITO, IZO, and ITZO on the passivation layer 130 and then patterning the transparent conductive layer by photolithography and etching processes.

As described above, according to the TFT substrate and the method of manufacturing the same in accordance with the present invention, the surface of the data pattern is implanted with ions to reduce the effect of the etchant and increase the adhesion force with the passivation layer formed by a subsequent process.

Moreover, it is possible to further increase the adhesion force with the passivation layer formed by a subsequent process by implanting ions into the overall surface of the data pattern and the interlayer insulating layer.

Accordingly, the present invention provides advantages in that the manufacturing process is simplified and the thickness of the product is reduced, compared to the conventional structure in which the inorganic passivation layer is formed between the source and drain metal layers and the organic passivation layer to increase the adhesion force.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A thin film transistor (TFT) substrate comprising:
an active layer including a channel region formed of a semiconductor and source and drain regions doped with impurities;
a data pattern formed on the active layer and including source and drain electrodes implanted with ions to increase hydrophobicity and roughness;
a passivation layer formed on the data pattern and including a pixel contact hole exposing a portion of the drain electrode; and
a pixel electrode formed on the passivation layer and connected to the drain electrode through the pixel contact hole.

2. The TFT substrate of claim 1, further comprising:
a gate insulating layer formed on the active layer;
a gate pattern formed on the gate insulating layer and including a gate electrode; and
an interlayer insulating layer formed on the gate pattern and including first and second contact holes exposing a portion of the source and drain regions.

3. The TFT substrate of claim 1, further comprising:
a gate pattern including a gate electrode;
a gate insulating layer formed between the gate pattern and the active layer; and
an ohmic contact layer formed of impurity-doped polysilicon on the active layer and exposing the channel region.

4. The TFT substrate of claim 1, wherein the passivation layer is an organic passivation layer.

5. The TFT substrate of claim 1, wherein the data pattern is formed of one selected from the group consisting of molybdenum tungsten (MoW), molybdenum (Mo), titanium (Ti), and titanium nitride (TiN).

6. The TFT substrate of claim 5, wherein the surface of the data pattern is implanted with carbon ions to increase hydrophobicity and roughness.

7. The TFT substrate of claim 2, wherein the surface of the interlayer insulating layer is implanted with ions.

8. The TFT substrate of claim 7, wherein the overall surface of the data pattern and the interlayer insulating layer is implanted with carbon ions.

9. A thin film transistor (TFT) substrate comprising:
an active layer formed on a substrate and including a channel region formed of a semiconductor and impurity-doped source and drain regions formed on both sides of the channel region;
a gate insulating layer covering the active layer;
a gate pattern formed on the gate insulating layer and including a gate line and a gate electrode connected to the gate line;
an interlayer insulating layer formed on the gate pattern and including a first contact hole exposing a portion of the source region and a second contact hole exposing a portion of the drain region;
a data pattern, the surface of which is implanted with ions, formed on the interlayer insulating layer, and including a source electrode connected to the source region through the first contact hole and a drain electrode connected to the drain region through the second contact hole;
a passivation layer formed on the data pattern and including a pixel contact hole exposing a portion of the drain electrode; and
a pixel electrode formed on the passivation layer and connected to the drain electrode through the pixel contact hole.

10. The TFT substrate of claim 9, wherein the gate pattern comprises:
a storage line formed parallel to the gate line; and
a storage electrode connected to the storage line and overlapping a portion of the drain electrode or the pixel electrode.

11. A thin film transistor (TFT) substrate comprising:
a gate pattern formed on a substrate and including a gate line and a gate electrode connected to the gate line;
a gate insulating layer covering the gate pattern;
an active layer formed on the gate insulating layer and including a channel region formed of a semiconductor and impurity-doped source and drain regions formed on both sides of the channel region;
an ohmic contact layer formed of impurity-doped polysilicon on the active layer and exposing the channel region;
a data pattern the surface of which is implanted with ions and including source and drain electrodes respectively formed on the ohmic contact layer;
a passivation layer formed on the data pattern and including a pixel contact hole exposing a portion of the drain electrode; and
a pixel electrode formed on the passivation layer and connected to the drain electrode through the pixel contact hole.

12. A method of manufacturing a thin film transistor substrate, comprising:
forming an active layer including a channel region formed of a semiconductor and impurity-doped source and drain regions;
forming a data pattern on the active layer, the data pattern including source and drain electrodes;
implanting ions into the surface of the data pattern to increase hydrophobicity and roughness;
forming a passivation layer on the data pattern, the passivation layer including a pixel contact hole exposing a portion of the drain electrode; and
forming a pixel electrode on the passivation layer, the pixel electrode being connected to the drain electrode through the pixel contact hole.

13. The method of claim 12, further comprising:
forming a gate insulating layer on the active layer;
forming a gate pattern including a gate electrode on the gate insulating layer; and
forming an interlayer insulating layer on the gate pattern, the interlayer insulating layer including first and second contact holes exposing a portion of the source and drain regions.

14. The method of claim 12, further comprising:
forming a gate pattern including a gate electrode;
forming a gate insulating layer between the gate pattern and the active layer; and
forming an ohmic contact layer on the active layer.

15. The method of claim 12, wherein the passivation layer is formed of an organic passivation layer.

16. The method of claim 12, wherein the data pattern is formed of one selected from the group consisting of molybdenum tungsten (MoW), molybdenum (Mo), titanium (Ti), and titanium nitride (TiN).

17. The method of claim 12, wherein implanting ions includes implanting carbon ions into the surface of the data pattern.

18. The method of claim 12, wherein implanting ions is selectively performed only to a region where the data pattern is formed.

19. The method of claim 12, wherein implanting ions is performed to the overall surface of the data pattern and the interlayer insulating layer.

20. A method of manufacturing a thin film transistor, comprising:
forming an active layer on a substrate, the active layer including a channel region formed of a semiconductor and impurity-doped source and drain regions formed on both sides of the channel region;
forming a gate insulating layer to cover the active layer;
forming a gate pattern on the gate insulating layer, the gate pattern including a gate line and a gate electrode connected to the gate line;
forming an interlayer insulating layer on the gate pattern, the interlayer insulating layer including a first contact hole exposing a portion of the source region and a second contact hole exposing a portion of the drain region;
forming a data pattern on the interlayer insulating layer, the data pattern including a source electrode connected to the source region through the first contact hole and a drain electrode connected to the drain region through the second contact hole;
implanting ions into the surface of the data pattern;
forming a passivation layer on the data pattern, the passivation layer including a pixel contact hole exposing a portion of the drain electrode; and
forming a pixel electrode on the passivation layer, the pixel electrode being connected to the drain electrode through the pixel contact hole.

21. The method of claim 20, wherein forming the gate pattern comprises:
forming a storage line parallel to the gate line, and a storage electrode connected to the storage line and overlapping a portion of the drain electrode or the pixel electrode.

22. A method of manufacturing a thin film transistor, comprising:
forming a gate pattern on a substrate, the gate pattern including a gate line and a gate electrode connected to the gate line;
forming a gate insulating layer to cover the gate pattern;
forming an active layer on the gate insulating layer, the active layer including a channel region formed of a semiconductor and impurity-doped source and drain regions formed on both sides of the channel region;
forming an ohmic contact layer on the active layer;
forming a data pattern on the ohmic contact layer, the data pattern including source and drain electrodes respectively connected to the source and drain regions;
implanting ions into the surface of the data pattern;
forming a passivation layer on the data pattern, the passivation layer including a pixel contact hole exposing a portion of the drain electrode; and
forming a pixel electrode on the passivation layer, the pixel electrode being connected to the drain electrode through the pixel contact hole.
